(19) United States
(12) Patent Application Publication
(10) Pub. No.: US 2016/0036468 A1
(43) Pub. Date: Feb. 4, 2016

(54) METHOD AND DEVICE FOR ITERATIVE DECODING A DATA TRANSFER STRUCTURE

(71) Applicant: Intel IP Corporation, Santa Clara, CA (US)

(72) Inventors: Sebastian ECKERT, Burgstaedt OT Mohsdorf (DE); Joan Anton OLIVELLA, Dresden (DE); Javad RAZAVILAR, San Diego, CA (US)

(21) Appl. No.: 14/449,554

(22) Filed: Aug. 1, 2014

(51) Int. Cl. H03M 13/37

(52) U.S. Cl. CPC H03M 13/3753

(57) ABSTRACT

A method for iterative decoding a data transfer structure comprising a plurality of code blocks includes: decoding a code block of the data transfer structure in a first iteration; determining a quantity indicative of a performance of the decoding of the code block; if the quantity indicates a decoding failure, decoding the code block again in subsequent iterations until a stopping criterion is reached, wherein the stopping criterion is based on a predetermined number of iterations per code block and a predetermined number of iterations per data transfer structure.

### TECHNICAL FIELD

The disclosure relates to a method and a device for iterative decoding a data transfer structure, in particular a transport block, comprising a plurality of code blocks, and more particularly to a hybrid threshold decoding termination criteria for high performance Turbo decoders improving battery-life for mobile devices.

### BACKGROUND

An iterative decoder such as a Turbo Decoder is based on an iterative algorithm that improves the likelihood estimations at each iteration. In the good cases, the decoder is capable to recover the original transmitted code block after a certain number of iterations. There are other cases in which the received signal is so corrupted that the decoder will not be able to recover the original code block even if the decoder runs more iterations. In general, the number of required iterations depends on the coding rate as well as the amount of corruption due to the transmission channel.

Turbo decoders use one threshold that stops decoding after achieving the maximum number of iterations allowed per code block. As a result, for one transport block transmission, Turbo decoders are dimensioned to support a total number of iterations which corresponds to the maximum number of iterations per code block times the number of code blocks. The code block threshold is defined as a compromise between the correction capabilities of the Turbo decoder and the amount of usable resources, e.g. hardware, MIPS, time, power consumption, clock frequency, etc. Decreasing the amount of usable resources, for example the clock frequency, has a negative impact on the Turbo decoder performance.

For these and other reasons there is a need for the present invention.

### BRIEF DESCRIPTION OF THE DRAWINGS

The accompanying drawings are included to provide a further understanding of embodiments and are incorporated in and constitute part of this specification. The drawings illustrate embodiments and together with the description serve to explain principles of embodiments. Other embodiments and many of the intended advantages of embodiments will be readily appreciated as they will become better understood by reference to the following detailed description. Like reference numerals designate corresponding similar parts.

FIG. 1 is a schematic diagram illustrating a communication system 100 in which a decoder for iterative decoding a data transfer structure according to the disclosure can be employed.

FIG. 2 is block diagram illustrating an iterative decoder 200 for decoding a code.

FIG. 3 is block diagram illustrating an iterative decoder 300 for decoding a turbo code.

FIG. 4 is a schematic diagram illustrating a transport block 400 according to a mobile communication standard.

FIG. 5 is block diagram illustrating an iterative decoder 500 for decoding a data transfer structure.

FIG. 6 is schematic diagram illustrating a method 600 for iterative decoding a data transfer structure.

FIG. 7 is schematic diagram illustrating a method 700 for iterative decoding a data transfer structure.

FIG. 8 is an exemplary histogram 800 illustrating a probability of appearance for number of half iterations required to decode a transport block.

FIG. 9 is a performance diagram 900 illustrating an exemplary throughput for an iterative decoder according to the disclosure for different stopping criteria characteristics.

### DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the present disclosure. The following detailed description, therefore, is not to be taken in a limiting sense, and the scope of the present disclosure is defined by the appended claims.

The various aspects summarized may be embodied in various forms. The following description shows by way of illustration various combinations and configurations in which the aspects may be practiced. It is understood that the described aspects and/or embodiments are merely examples, and that other aspects and/or embodiments may be utilized and structural and functional modifications may be made without departing from the scope of the present disclosure. In particular, it is to be understood that the features of the various exemplary embodiments described herein may be combined with each other, unless specifically noted otherwise.

As employed in this specification, the terms “coupled” and/or “electrically coupled” are not meant to mean that the elements must be directly coupled together; intervening elements may be provided between the “coupled” or “electrically coupled” elements.

The iterative decoders described herein may be employed in devices of wireless communication systems, in particular in receivers and transceivers. They may be employed in base stations as well as in mobile stations.

The iterative decoders described herein maybe configured to decode any kinds of error correcting codes for which iterative decoding applying a forward recursion and a backward recursion may be used. In particular, the iterative decoders described herein may be configured to decode convolutional codes and/or concatenated codes, e.g. parallel concatenated convolutional codes such as e.g. turbo codes. Such decoders may be used in telecommunications systems based on the UMTS (Universal Mobile Telecommunications System) standard, e.g. HSDPA (High Speed Downlink Packet Access) or HSUPA (High Speed Uplink Packet Access), and long term evolution (LTE).

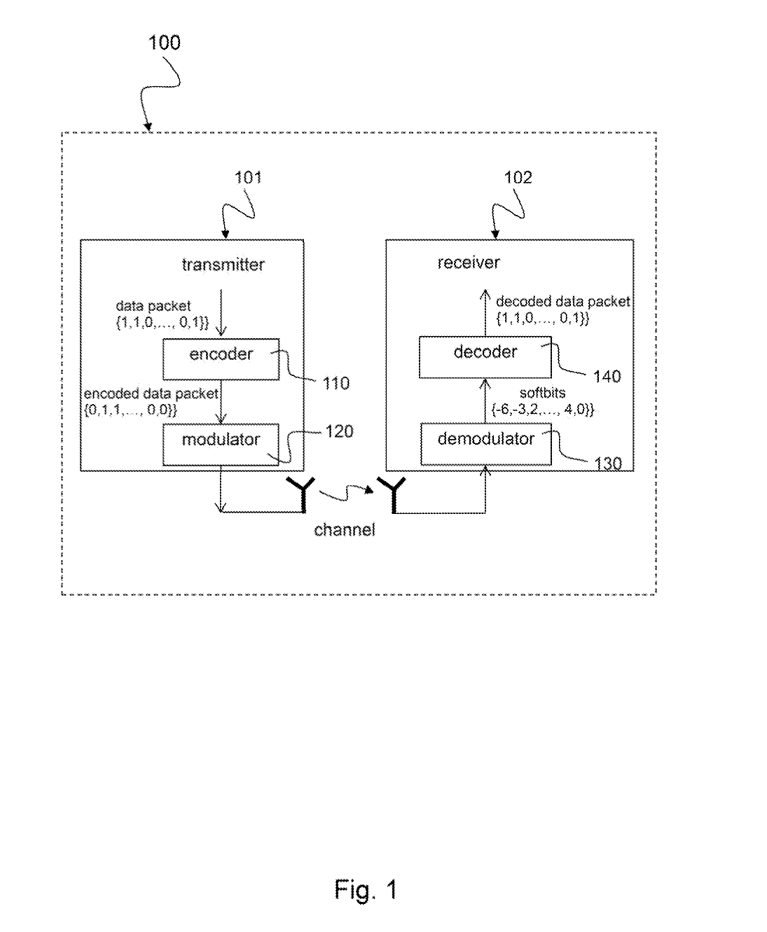

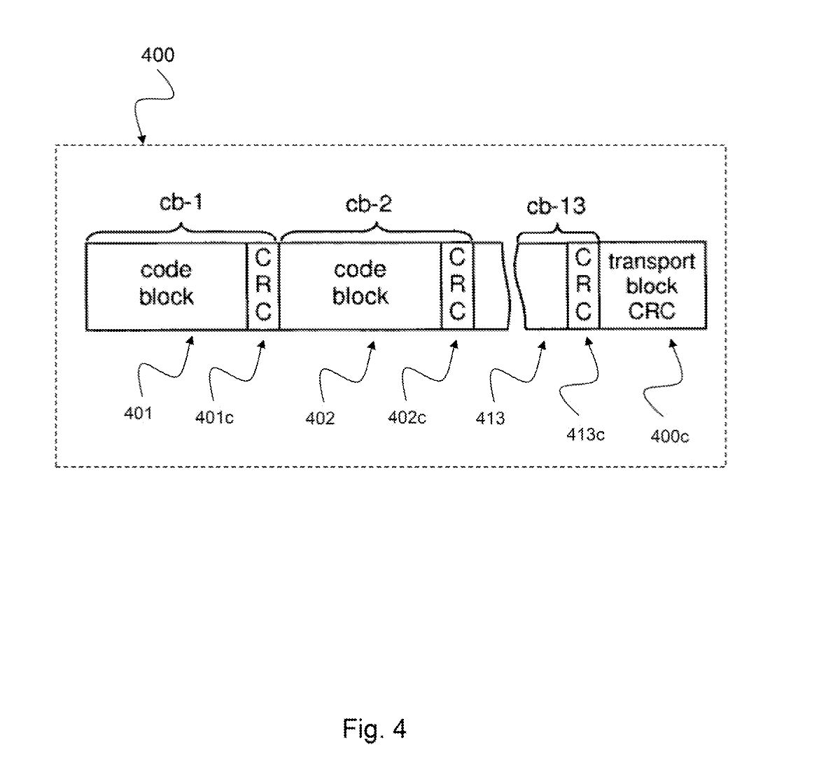

In the following data transfer structures are described. A data transfer structure is a data packet comprising a plurality of data sub-packets, e.g. a plurality of data blocks. A transport block comprising a plurality of code blocks, e.g. as described below with respect to FIG. 4, is one example of a data transfer structure. A data transfer structure maybe used for data transfer between different physical or logical units, for example for transfer over a communication channel as shown below in FIG. 1.

The methods and devices described in the following may be based on cyclic redundancy checks. A cyclic redundancy check (CRC) is an error-detecting code for detecting accidental changes to raw data. Blocks of data entering these systems get a short check value attached (the so called CRC value) that may be based on the remainder of a polynomial division of their contents. On retrieval the calculation is repeated, and corrective action can be taken against presumed data corruption if the check values do not match.

FIG. 1 is a schematic diagram illustrating a communication system. 100 in which a decoder for iterative decoding a data transfer structure according to the disclosure can be employed. The communication system 100 comprises a transmitter 101 and a receiver 102 which are connected through a radio channel. In transmitter 101 subsequent data packets comprised of individual data bits are encoded (at encoder 110) by some known encoding technique. Any of this encoding technique causes an increase of the bits of each packet, for example, turbo coding in LTE may imply a tripling of the bit number. The encoded data packets are then modulated (at modulator 120) by any known modulation scheme, and the modulated bit stream is fed to an antenna for transmission.

At the receiver's side the received bit stream is demodulated (at demodulator 130), and the receiver 102 computes softbits for each received and demodulated bit (log-likelihood ratios), which represent a reliability measure for the received data packet. The sign of a softbit corresponds to the likelihood of a demodulated bit being 0 or 1. The magnitude of a softbit is a measure for the reliability of the respective sign information (for example in a range of +/−7 corresponding to a resolution of 4 bits). The softbits are now decoded (at decoder 140) and the decoded data packets are checked for decoding errors, e.g. by evaluating a cyclic redundancy check (CRC) sum.

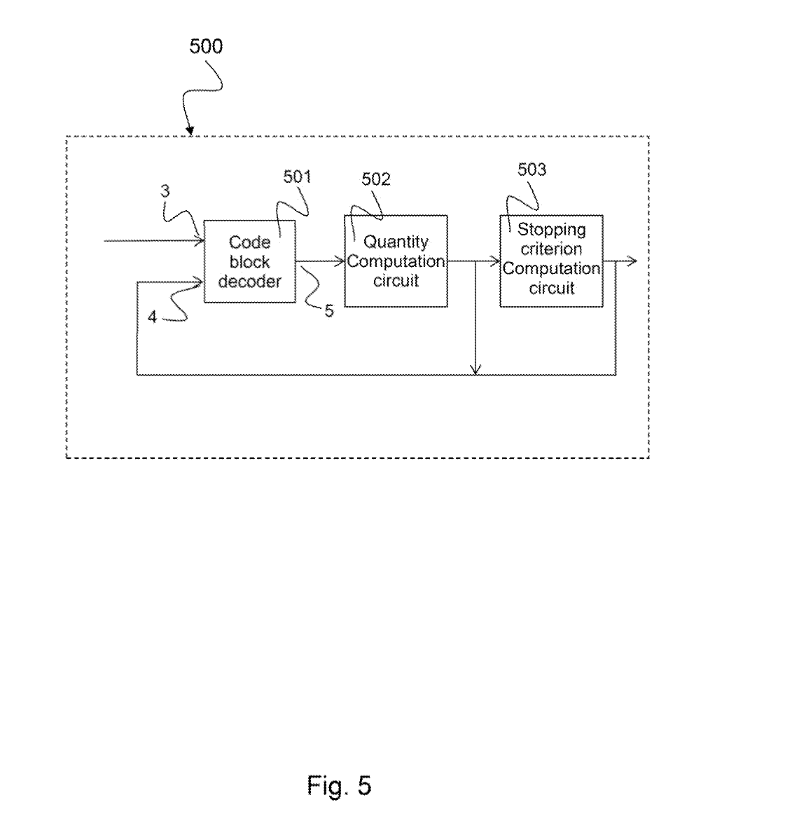

The decoder 140 may correspond to one of the decoders for iterative decoding a data transfer structure as described hereinafter. The computation of a CRC checksum is one example of determining a quantity indicating a decoding failure or decoding success as described below with respect to FIGS. 5 to 7. Another such example is using a decoding metric for deciding about failure or success of the decoding.

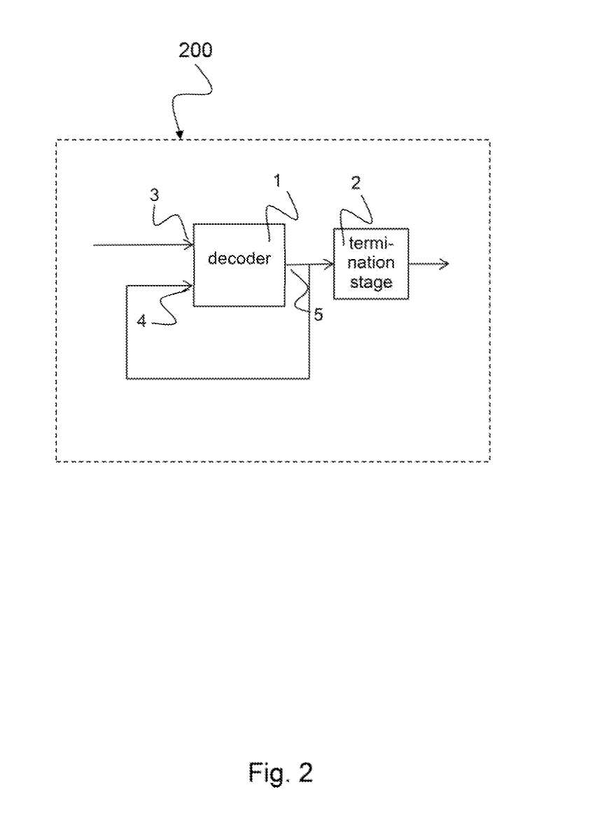

FIG. 2 illustrates an exemplary iterative decoder 200. The iterative decoder 200 comprises a decoder 1 and a termination stage 2. The decoder 1 decodes code blocks received at an input 3 and has an output 5 to provide a sequence of reliability data representative of estimates of the originally transmitted (systematic) data bits. Further, the decoder 1 has an input 4 for a-priori information.

The decoder 1 decodes the code blocks received at input 3. Typically, a code block is represented by sequence of soft values which comprise systematic information and parity information. The systematic information corresponds to the original transmitted data sequence. The parity information corresponds to parity information generated by one or more encoders (e.g. convolutional encoders) at the transmitter.

In iterative decoding, decoding results such as e.g. the estimates provided at output 5 are fed back to the input 4 of decoder 1 and are used as a-priori information in the next decoding iteration. This iteration is continued until a maximum number of allowed iterations is reached or another stopping criterion is satisfied.

The estimates provided at output 5 are input into the termination stage 2. When the stopping criterion is satisfied, the iterative decoding process is stopped and the estimates of the systematic data are output from the termination stage 2. By way of example, a stopping criterion may be satisfied if a sufficient amount of convergence of estimates generated in consecutive iterations at output 5 is reached.

Decoder 1 may be designed as a symbol-by-symbol a-posteriori probability (APP) decoder. APP decoders may operate on a trellis diagram. A trellis diagram is a representation of the encoder states versus discrete time. By way of example, decoder 1 may be designed as SISO (Soft-Input-Soft-Output) decoder.

The decoder 200 may correspond to one of the decoders for iterative decoding a data transfer structure as described hereinafter. The termination stage 2 may use a stopping criterion as described below with respect to FIGS. 5 to 7 to decide about terminating the decoding.

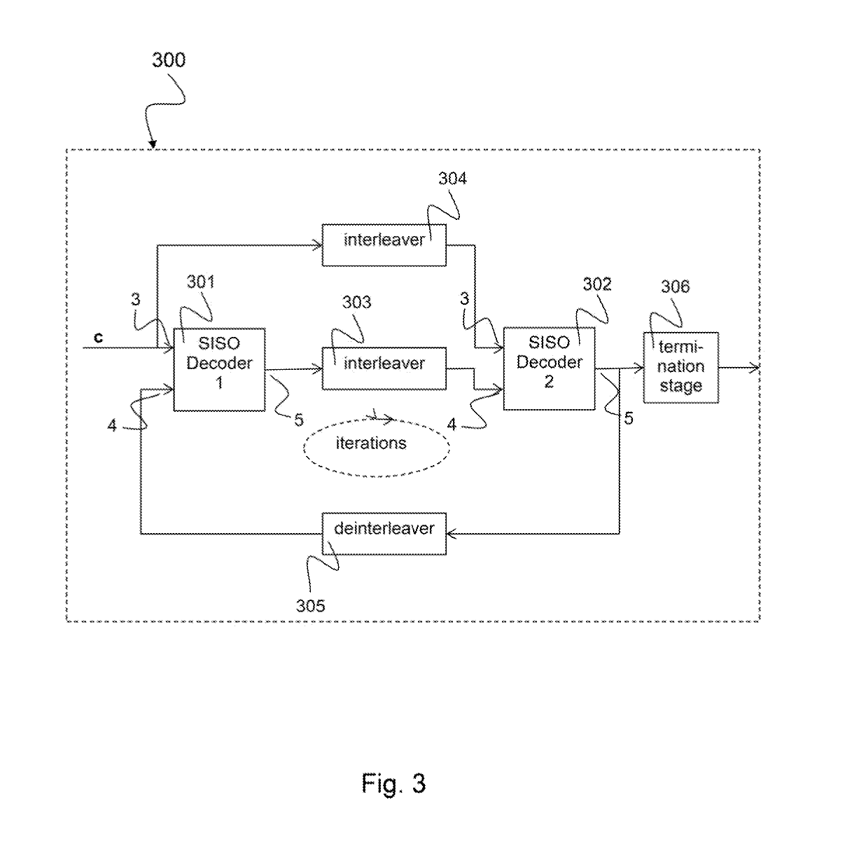

FIG. 3 illustrates the principle design of an iterative decoder 300 for decoding a turbo code. The iterative decoder 300 is designed according to the principles of iterative decoder 200 shown in FIG. 2. More specifically, iterative decoder 300 may comprise a first component decoder 301, a second component decoder 302 and an interleaver 303 coupled between an output of the first component decoder 301 and an input of the second component decoder 302. The first component decoder 301 and the second component decoder 302 may e.g. be designed as APP decoders, i.e. may be identical with decoder 1 in FIG. 2. By way of example, the first component decoder 301 and the second component decoder 302 may be designed as SISO (soft-input soft-output) decoders. Each SISO decoder 301, 302 estimates the symbol-by-symbol a-posteriori probability.

The iterative decoder 300 may further comprise an interleaver 304, a de-interleaver 305 and a termination stage 306. The termination stage 306 may be similar to the termination stage 2 in iterative decoder 300, and reference is made to the corresponding description.

The first component decoder 301 receives at input 3 systematic data and parity data produced by a turbo encoder in the transmitter and reconstructed by a demodulator (not shown) in the receiver. Since the signal received at the receiver is usually distorted by noise and interference, the demodulator can only provide estimates of the systematic data and parity data generated by the turbo encoder. Typically, these estimates are provided to the turbo decoder 300 in the form of log-likelihood ratios (LLRs). LLRs express the ratio between the probabilities of the transmitted bits being 0 and being 1, given the received analog signal.

The first component decoder 301 works on the sequence of systematic data and parity data received at input 3 in natural order. The first component decoder 301 computes a-posteriori probabilities of the transmitted systematic data from the LLRs of the systematic data and associated parity data received at input 3, and from the a-priori information received at input 4. The second component decoder 301 computes a-posteriori probabilities of the interleaved systematic data from the LLRs received at a-priori information input 4 and associated interleaved parity data received at input 3. Thus, the output of the interleaver 203 is used as a-priori information in the second component decoder 302.

In subsequent iterations each component decoder 301, 302 uses the so-called extrinsic information output by the other component decoder 301, 302 in the preceding half-iteration as a-priori information.

It is to be noted that FIG. 3 is a simplified block diagram of a turbo decoder. As known in the art, the first and second component decoders 301, 302 may work on different parts of code block data. By way of example, a received code block c=(u, p₁, p₂) may comprise the systematic sequence u, a first parity sequence p₁ and a second parity sequence p₂. (all these sequences are typically distorted by noise and interference). In this case, by way of example, the systematic sequence u and the first parity sequence p₁ may be used at the input 3 of the first component decoder 301, and the interleaved systematic sequence u_{T} and the second parity sequence p₂ may be used at the input 3 of the second component decoder 301.

The optimal algorithm to produce the APP is the so-called Bahl, Cocke, Jelinek, and Raviv (BCJR) algorithm. According to the theoretical BCJR algorithm or to other sub-optimal algorithms, the APP decoder 1, 301, 302 computes forward metrics α and backward metrics β and then the output metrics (i.e. the sequence of reliability data; for decoder 1, this sequence corresponds to the estimates of the original transmitted data sequence). The α- and β-metrics are gathered in a forward and backward recursion, respectively.

The iterative decoder 300 may correspond to one of the decoders for iterative decoding a data transfer structure as described below with respect to FIGS. 5 to 7. The termination stage 306 may use a stopping criterion as described below with respect to FIGS. 5 to 7 to decide about terminating the decoding.

FIG. 4 illustrates a transport block 400 according to a mobile communication standard as one example of a data transfer structure. The transport block 400 comprises a plurality of code blocks 401, 402, 413. A respective CRC field, for example a single bit or a field of bits evaluating the CRC over the respective code block may, e.g., be attached to each code block 401, 402, 413 and a transport block CRC field evaluating the CRC over the full transport block may, e.g., be attached to the transport block. The transport block may be specified according to a mobile communication standard, e.g. LTE (Long Term Evolution).

FIG. 5 is block diagram illustrating an iterative decoder 500 for decoding a data transfer structure comprising a plurality of code blocks.

The iterative decoder 500 includes a code block decoder 501 configured to iteratively decode a code block of the data transfer structure. The data transfer structure may correspond to a data transport block 400 as shown above in FIG. 4. The iterative decoder 500 includes a quantity computation circuit 502 coupled to an output 5 of the code block decoder 501. The quantity computation circuit 502 computes a quantity indicative of a performance of the decoding of the code block, e.g. a CRC checksum or a metric of the decoding such as a soft-bit metric. The iterative decoder 500 includes a stopping criterion computation circuit 503 for computing a stopping criterion for the iterative code block decoding based on a predetermined number of iterations per code block and a predetermined number of iterations per data transfer structure. If the stopping criterion indicates a failure, decoding of the code block may be repeated in subsequent iterations. If the stopping criterion indicates a success, decoding of the next code block may be performed.

The code block decoder 501 may correspond to the decoder 1 described above with respect to FIG. 2 or to the iterative decoder 300 (without termination stage 306) described above with respect to FIG. 3. The stopping criterion computation circuit 503 may correspond to the termination stage 306 described above with respect to FIG. 3.

The quantity computation circuit 502 may include a CRC circuit for computing a cyclic redundancy check over at least part of the code block. The quantity computation circuit 502 may include a metric computation circuit for computing a metric of the decoding of the code block. In one example, the code block decoder 501 is a Turbo decoder.

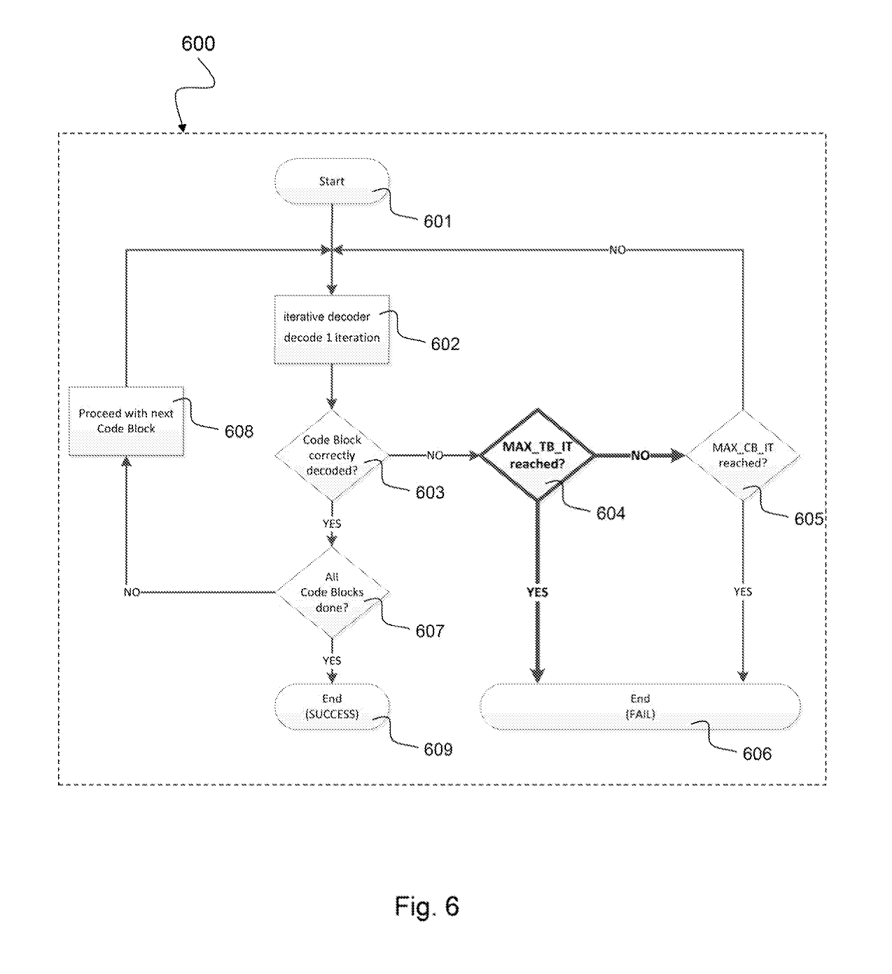

FIG. 6 is schematic diagram illustrating an exemplary method 600 for iterative decoding a data transfer structure.

The decoding starts 601 with the first code block of the data transfer structure. The decoding 602 performs one iteration each time. Some systems refer to two half-iterations, the linear half-iteration and the interleaved half-iteration. After each iteration, the implementation checks 603 whether the code block could be correctly decoded. In some systems such as LTE systems this can be achieved by checking the code block CRC. If the code block has been correctly decoded (CRC OK), then the decoding proceeds 608 with the next code block of the data transfer structure if not all code blocks have been decoded 607. If all code blocks are decoded the decoding may end successfully 609.

After each iteration, if the code block could not be correctly decoded (e.g. CRC failed), in a first check 604 it is checked if the maximum of allowed iterations per data transfer structure MAX_TB_IT has been reached. This check 604 counts the accumulated iterations so far for all code blocks of the current data transfer structure and compares it against the maximum number of allowed iterations per data transfer structure MAX_TB_IT. If this maximum MAX_TB_IT is reached, the decoding of the code block and the current data transfer structure is stopped 606. If this maximum MAX_TB_IT is not reached, in a second check 605 succeeding the first check 604 it is checked if the maximum of allowed iterations per code block MAX_CB_IT has been reached. If the maximum MAX_CB_IT is reached, the decoding of the code block is considered to have failed and therefore the decoding of the data transfer structure stops 606. Otherwise, the decoding runs a new iteration 602 on that same code block. The first check 604 and the second check 605 may be exchanged. In one example, the following relation holds: MAX_TB_IT<<NUM_CB*MAX_CB_IT, where NUM_CB denotes the number of code blocks in one data transfer structure.

The method 600 may be applied to an iterative decoder 500 as described above with respect to FIG. 6. In particular, the decoding 602 may be performed by the code block decoder 501, the check 603 if the code block has been correctly decoded may be performed by the quantity computation circuit 502 and the first check 604 with respect to MAX_TB_IT and the second check 605 with respect to MAX_CB_IT may be performed by the stopping criterion computation circuit 503.

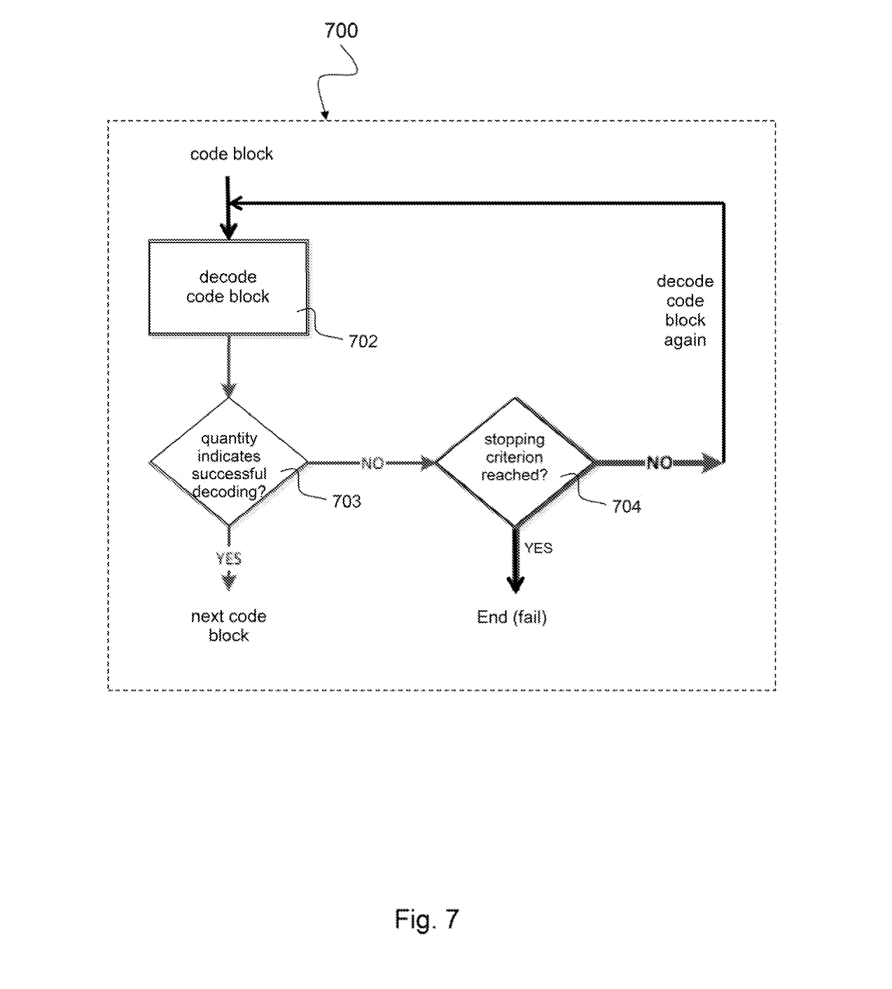

FIG. 7 is schematic diagram illustrating a method 700 for iterative decoding a data transfer structure comprising a plurality of code blocks.

The method 700 is a generalization of the decoding 602, the check 603 if the code block has been correctly decoded and the first check 604 and second check 605 as described above with respect to FIG. 6.

The method 700 includes decoding 702 a code block of the data transfer structure in a first iteration. The method 700 includes determining a quantity 703 indicative of a performance of the decoding of the code block. If the quantity indicates a decoding failure, the method 700 includes decoding the code block again in subsequent iterations until a stopping criterion is reached 704. The stopping criterion is based on a predetermined number of iterations per code block and a predetermined number of iterations per data transfer structure, e.g. corresponding to MAX_TB_IT of the first check 604 and MAX_CB_IT of the second check 605 as described above with respect to FIG. 6.

The predetermined number of iterations per data transfer structure MAX_TB_IT may be smaller than the predetermined number of iterations per code block MAX_CB_IT times a number of code blocks contained in the data transfer structure NUM_CB. Determining the quantity 703 may include performing a cyclic redundancy check over at least part of the code block. The method 700 may include decoding a next code block of the data transfer structure if the quantity indicates a success. The method 700 may include stopping 704 the decoding of the data transfer structure (end with fail) if either the predetermined number of iterations per code block MAX_CB_IT or the predetermined number of iterations per data transfer structure MAX_TB_IT are reached. Decoding the code block may be based on Turbo decoding.

The predetermined number of iterations per data transfer structure MAX_TB_IT may be variable. The predetermined number of iterations per data transfer structure MAX_TB_IT may depend on a code rate of the decoding. The predetermined number of iterations per data transfer structure MAX_TB_IT may depend on a number of retransmissions of the code blocks. The predetermined number of iterations per data transfer structure MAX_TB_IT may depend on a transmission bandwidth. The predetermined number of iterations per data transfer structure MAX_TB_IT may depend on a throughput of the decoding. The predetermined number of iterations per data transfer structure MAX_TB_IT may depend on a clock rate of the decoding. The predetermined number of iterations per data transfer structure MAX_TB_IT may depend on a network load or a perceived network load at the UE (user equipment). The predetermined number of iterations per data transfer structure MAX_TB_IT may depend on a transmission scheme, e.g. LTE, WiFi, etc. The predetermined number of iterations per data transfer structure MAX_TB_IT may depend on at least one of a layer, a channel and a carrier over which the code block is transmitted. The predetermined number of iterations per data transfer structure MAX_TB_IT may depend on an evaluation of the statistics of the number of iterations needed for decoding a data transfer structure. The data transfer structure may be a transport block in a mobile communication standard as described above with respect to FIG. 4. The predetermined number of iterations per data transfer structure MAX_TB_IT may depend on multiple of the above mentioned parameters.

The method 700 may be applied to an iterative decoder 500 as described above with respect to FIG. 6. In particular, the decoding 702 may be performed by the code block decoder 501, the check 703 if the code block has been correctly decoded may be performed by the quantity computation circuit 502 and the stopping criterion checking 704 may be performed by the stopping criterion computation circuit 503.

The methods and devices for iterative decoding described in the disclosure allow to design the system in order to support a certain limited budget of iterations. The total system budged is then shared by the code blocks. The budget does not have to be equally shared among the code blocks. In contrast, a particular code block can still make use of a greater number of iterations than other code blocks if needed, even though this implies that less iterations are then available for the remaining code blocks. In other words, the methods and devices for iterative decoding described in the disclosure may make use of statistical diversity and may balance the budget among the code blocks.

The method 700 can be extended to share the total system budget of iterations between different data transfer structures as well. For example, the total system budget can be defined for all layers and/or for all carriers, etc. Then, code blocks of different layers or carriers may share the same system budget of iterations as described in the following.

The method 700 can be extended for iterative decoding a data transfer structure of a plurality of data transfer structures, wherein the data transfer structure comprises a plurality of code blocks. Such an extended method 700 includes: decoding 702 a code block of the data transfer structure in a first iteration; determining a quantity 703 indicative of a performance of the decoding of the code block; and if the quantity indicates a decoding failure, decoding the code block again in subsequent iterations until a stopping criterion is reached 704. For the extended method 700 such a stopping criterion may evaluate the total available system resources. The stopping criterion 704 may for example be based on a predetermined number of iterations per code block MAX_CB_IT and a total available number of iterations with respect to the plurality of data transfer structures. The total available number of iterations with respect to the plurality of data transfer structures may be defined as MAX_TB_IT*NUM_TB, where MAX_TB_IT denotes the maximum number of iterations allowed per data transfer structure and NUM_TB denotes the number of data transfer structures contained in the plurality of data transfer structures to be decoded.

In one example, the total available number of iterations with respect to the plurality of data transfer structures is smaller than the predetermined number of iterations per code block MAX_CB_IT times a number of code blocks NUM_CB contained in one data transfer structure times a number of data transfer structures NUM_TB of the plurality of data transfer structures.

The total available number of iterations may be shared between code blocks of different layers and/or code blocks of different carriers.

The extended method 700 may further include: determining a channel quality of the data transfer structure; and decoding the code blocks of the data transfer structure based on the determined channel quality. The decoding of the data transfer structure may be prioritized based on the determined channel quality.

The extended method 700 as described above maybe applied to an iterative decoder 500 as described above with respect to FIG. 6. In particular, the decoding 702 may be performed by the code block decoder 501, the check 703 if the code block has been correctly decoded may be performed by the quantity computation circuit 502 and the stopping criterion checking 704 may be performed by the stopping criterion computation circuit 503.

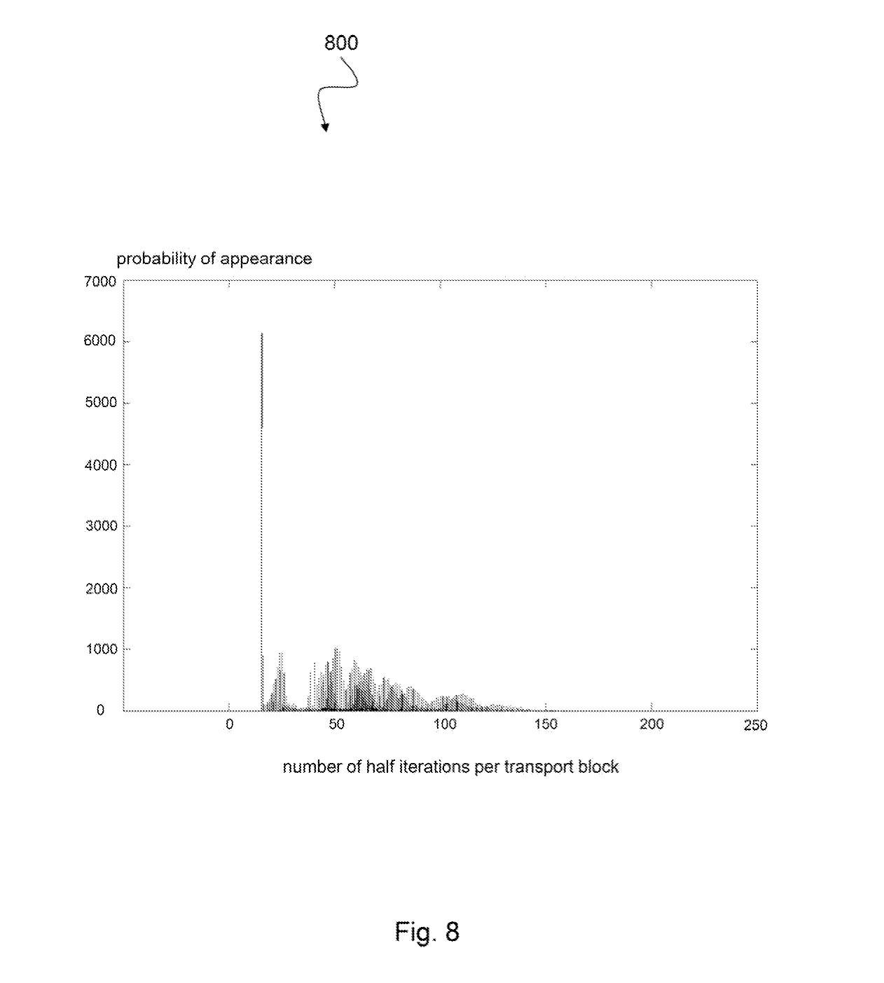

FIG. 8 is an exemplary histogram 800 illustrating a probability of appearance for a number of half iterations required to decode a transport block by using a Turbo decoder. FIG. 8 displays the histogram of the number of half iterations required in a 20 MHz cell with 100 PRBs (physical resource blocks) and an assigned MCS (modulation coding scheme) in an LTE transmission scenario. In this example, 16 half-iterations are allowed per code block. This means that the Turbo decoder may be designed to allow in the worst case 16 half-iterations times 13 code blocks, i.e. 208 half-iterations per transport block. Therefore, it is possible that, while decoding, the Turbo decoder may run 208 half-iterations per transport block. However, as it can be seen in the histogram, the probability that this happens is extremely low. Not only that, it can be observed that in very rare occasions the Turbo decoder may make use of more than, let's say, 150 half-iterations.

Methods and devices as described in this disclosure may make use of this statistical behavior. So the iterative decoder 500 and the methods 600, 700 for iterative decoding as described above with respect to FIGS. 5 to 7 may be designed to support a maximum number of half-iterations much less than the 208 half-iterations per transport block required in the worst case scenario. Instead, only a certain number of half-iterations (for example, 150 half-iterations) may be allowed per data transfer structure or transport block. This is a big saving in hardware resources with a very little impact on the performance.

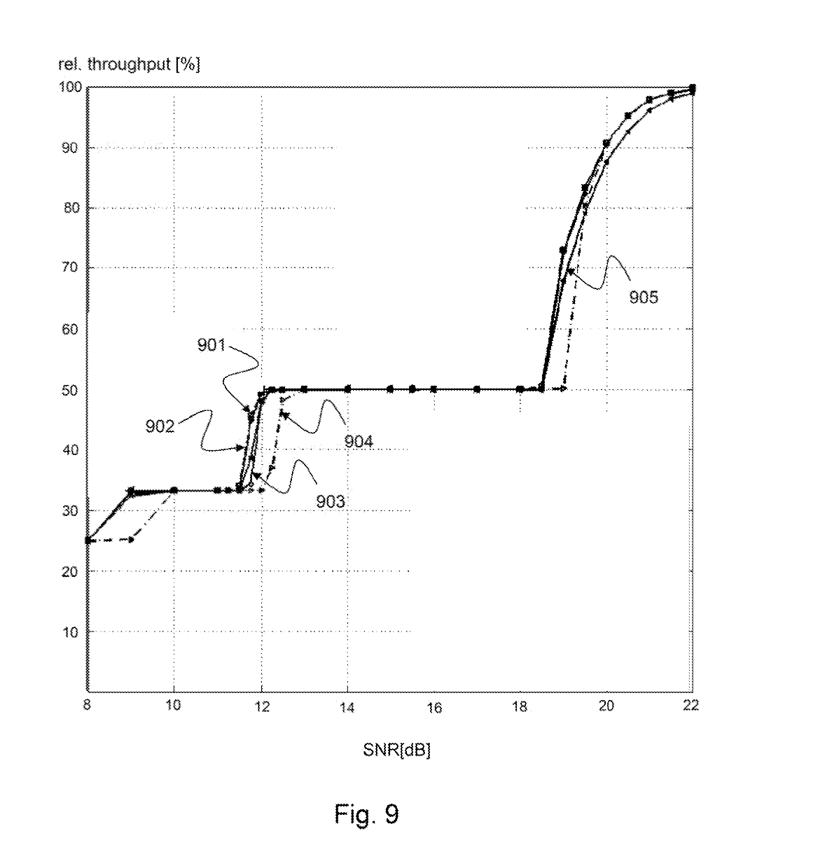

FIG. 9 is a performance diagram 900 illustrating an exemplary throughput for an iterative decoder according to the disclosure for different stopping criteria characteristics.

The transmission scenario is a 20 MHz LTE cell with 100 PRBs allocated. The impact on the assigned MCS is shown by displaying five curves with different parameters for stopping criteria characteristics. The data transfer structure is realized by a transport block as defined by LTE mobile communication standard.

The first curve 901 displays the performance of a reference decoder. 16 half-iterations are allowed per code block. This means that a maximum of 16 half-iterations times 13 code blocks, i.e., 208 half-iterations per transport block are allowed.

The second curve 902 limits the number of half-iterations per transport block down to 150 half-iterations by using a method as described in this disclosure. The performance impact is very little and the power consumption of the Turbo decoder can be reduced down to 150/208, i.e. 72%.

The third curve 903 limits the number of half-iterations per transport block down to 130 half-iterations by using a method as described in this disclosure. The performance impact is still little and the power consumption of the Turbo decoder can be reduced down to 130/208, i.e. 62%.

The fourth curve 904 limits the number of half-iterations per transport block down to 100 half-iterations by using a method as described in this disclosure. The performance impact is high even though the power consumption of the Turbo decoder can be reduced down to 100/208, i.e. 48%.

The fifth curve 905 shows the performance impact of using a Turbo decoder using a stopping criterion based on the worst case, i.e. number of allowed iterations corresponds to maximum number of iterations allowed per code block MAX_CB_IT times number of code blocks NUM_CB in one transport block, in order to achieve similar power savings. For such similar power savings, the number of iterations allowed per code block MAX_CB_IT must be decreased down to 11. With 11 half-iterations per code block, the maximum required half-iterations are 143. It can be observed that for a similar power saving the performance impact is much greater than with the methods and devices as described in this disclosure.

In high throughput scenarios, rather good channel conditions are expected. Therefore, the standards tend to specify rather high code rates for such scenarios. Not only this but also the retransmissions tend to add an energy gain more than a coding gain. This is the case for LTE with a 20 MHz bandwidth. For the maximum throughput and greater code rates, the LTE standard defines a Limited Buffer Rate Matching (LBRM). As a result, in such high throughput scenarios, the average number of required iterations on the Turbo Decoder is lower than in cases with lower code rate. In general, the greater the coding gain (lower code rate), the more can the Turbo Decoder gain by running more iterations. Therefore, it is in such conditions (LTE, 20 MHz, LBRM) where the methods and devices as described in this disclosure provide a better fit as can be seen from FIG. 9.

In this disclosure an iterative decoding algorithm is described that allows a reduction of the total required number of iterations over a data transfer structure or a transport block. Methods and devices as described in this disclosure maybe based on a hybrid threshold approach for the decoding termination criteria in conjunction with a code block early termination criterion. The iterative decoder may stop decoding a code block when the code block is successfully decoded (early termination criterion) and may proceed with the following code block. The iterative decoder may implement a first threshold for the maximum number of iterations per code block at each code block. A second threshold may then be added for a maximum sum of iterations over the entire data transfer structure. So, during the decoding process, the decoding may stop at any point in time that the sum of iterations for the already processed code blocks exceeds the maximum allowed iterations per data transfer structure or at any point in time that the iterations for one code block exceed the maximum allowed iterations per code block. This data transfer structure threshold may be significantly smaller than the maximum number of iterations per code block times the number of code blocks. By this means, the used resources, i.e. hardware, MIPS, time, power consumption, clock frequency, etc. can be significantly reduced while maintaining very similar correction capabilities.

### EXAMPLES

Example 1 is method for iterative decoding a data transfer structure comprising a plurality of code blocks, the method comprising: decoding a code block of the data transfer structure in a first iteration; determining a quantity indicative of a performance of the decoding of the code block; if the quantity indicates a decoding failure, decoding the code block again in subsequent iterations until a stopping criterion is reached, wherein the stopping criterion is based on a predetermined number of iterations per code block and a predetermined number of iterations per data transfer structure.

In Example 2, the subject matter of Example 1 can optionally include that the predetermined number of iterations per data transfer structure is smaller than the predetermined number of iterations per code block times a number of code blocks contained in the data transfer structure.

In Example 3, the subject matter of any one of Examples 1-2 can optionally include that determining the quantity comprises performing a cyclic redundancy check over at least part of the code block.

In Example 4, the subject matter of any one of Examples 1-3 can optionally include decoding a next code block of the data transfer structure if the quantity indicates a success.

In Example 5, the subject matter of any one of Examples 1-4 can optionally include stopping the decoding of the data transfer structure if either the predetermined number of iterations per code block or the predetermined number of iterations per data transfer structure is reached.

In Example 6, the subject matter of any one of Examples 1-5 can optionally include that decoding the code block is based on Turbo decoding.

In Example 7, the subject matter of any one of Examples 1-6 can optionally include that the predetermined number of iterations per data transfer structure is variable.

In Example 8, the subject matter of any one of Examples 1-7 can optionally include that the predetermined number of iterations per data transfer structure depends on a code rate of the decoding.

In Example 9, the subject matter of any one of Examples 1-8 can optionally include that the predetermined number of iterations per data transfer structure depends on a number of retransmissions of the code blocks.

In Example 10, the subject matter of any one of Examples 1-9 can optionally include that the predetermined number of iterations per data transfer structure depends on a transmission bandwidth.

In Example 11, the subject matter of any one of Examples 1-10 can optionally include that the predetermined number of iterations per data transfer structure depends on a throughput of the decoding.

In Example 12, the subject matter of any one of Examples 1-11 can optionally include that the predetermined number of iterations per data transfer structure depends on a clock rate of the decoding.

In Example 13, the subject matter of any one of Examples 1-12 can optionally include that the predetermined number of iterations per data transfer structure depends on a transmission scheme.

In Example 14, the subject matter of any one of Examples 1-13 can optionally include that the predetermined number of iterations per data transfer structure depends on at least one of a layer, a channel and a carrier over which the code block is transmitted.

In Example 15, the subject matter of any one of Examples 1-14 can optionally include that the predetermined number of iterations per data transfer structure depends on an evaluation of the statistics of the number of iterations needed for decoding a data transfer structure.

In Example 16, the subject matter of any one of Examples 1-15 can optionally include that the data transfer structure is a transport block in a mobile communication standard.

Example 17 is an iterative decoder for iterative decoding a data transfer structure comprising a plurality of code blocks, the iterative decoder comprising: a code block decoder configured to iteratively decode a code block of the data transfer structure; a quantity computation circuit configured to compute a quantity indicative of a performance of the decoding of the code block; a stopping criterion computation circuit configured to compute a stopping criterion for the iterative code block decoding based on a predetermined number of iterations per code block and a predetermined number of iterations per data transfer structure.

In Example 18, the subject matter of Example 17 can optionally include that the quantity computation circuit comprises a CRC circuit configured to compute a cyclic redundancy check over at least part of the code block.

In Example 19, the subject matter of Example 17 can optionally include that the quantity computation circuit comprises a metric computation circuit configured to compute a metric of the decoding of the code block.

In Example 20, the subject matter of any one of Examples 17-19 can optionally include that the code block decoder comprises a Turbo decoder.

Example 21 is a method for iterative decoding a data transfer structure of a plurality of data transfer structures, the data transfer structure comprising a plurality of code blocks, the method comprising: decoding a code block of the data transfer structure in a first iteration; determining a quantity indicative of a performance of the decoding of the code block; and if the quantity indicates a decoding failure, decoding the code block again in subsequent iterations until a stopping criterion is reached, wherein the stopping criterion is based on a predetermined number of iterations per code block and a total available number of iterations with respect to the plurality of data transfer structures.

In Example 22, the subject matter of Example 21 can optionally include that the total available number of iterations is smaller than the predetermined number of iterations per code block times a number of code blocks contained in the data transfer structure times a number of data transfer structures of the plurality of data transfer structures.

In Example 23, the subject matter of any one of Examples 21-22 can optionally include that the total available number of iterations is shared between code blocks of different layers and/or code blocks of different carriers.

In Example 24 the subject matter of any one of Examples 21-23 can optionally include determining a channel quality of the data transfer structure; and decoding the code blocks of the data transfer structure based on the determined channel quality.

In Example 25, the subject matter of Example 24 can optionally include prioritizing the decoding of the data transfer structure based on the determined channel quality.

Example 26 is a computer readable medium on which computer instructions are stored which when executed by a computer, cause the computer to perform the method of one of Examples 1 to 16 and 21 to 25.

Example 27 is an iterative decoder for iterative decoding a data transfer structure comprising a plurality of code blocks, the iterative decoder comprising: decoding means for decoding a code block of the data transfer structure in a first iteration; determining means for determining a quantity indicative of a performance of the decoding of the code block; if the quantity indicates a decoding failure, the decoding means is configured to decode the code block again in subsequent iterations until a stopping criterion is reached, wherein the stopping criterion is based on a predetermined number of iterations per code block and a predetermined number of iterations per data transfer structure.

In Example 28, the subject matter of Example 27 can optionally include that the predetermined number of iterations per data transfer structure is smaller than the predetermined number of iterations per code block times a number of code blocks contained in the data transfer structure.

In Example 29, the subject matter of any one of Examples 27-28 can optionally include that the determining means is configured to perform a cyclic redundancy check over at least part of the code block.

In Example 30, the subject matter of any one of Examples 27-29 can optionally include the decoding means is configured to decode a next code block of the data transfer structure if the quantity indicates a success.

In Example 31, the subject matter of any one of Examples 27-30 can optionally include stopping means for stopping the decoding of the data transfer structure if either the predetermined number of iterations per code block or the predetermined number of iterations per data transfer structure is reached.

In Example 32, the subject matter of any one of Examples 27-31 can optionally include that the decoding means are configured to decode the code block based on Turbo decoding.

In Example 33, the subject matter of any one of Examples 27-32 can optionally include that the predetermined number of iterations per data transfer structure is variable.

Example 34 is a transmission system, comprising: a transmitter configured to transmit a data transfer structure over a transmission channel and a receiver, wherein the receiver comprises an iterative decoder according to any one of Examples 17-20.

In Example 35, the subject matter of Example 34 can optionally include that the transmitter is an OFDM transmitter and the receiver is an OFDM receiver.

In Example 36, the subject matter of any one of Examples 34-35 can optionally include that the receiver is configured to process a data transfer structure received at a receive port of the receiver in response to a data transfer structure transmitted at the transmitter.

In Example 37, the subject matter of any one of Examples 34-36 can optionally include that the transmitter comprises an encoder configured to encode a data packet providing an encoded data packet; and a modulator configured to modulate the encoded data packet providing the data transfer structure.

In Example 38, the subject matter of any one of Examples 34-37 can optionally include that the receiver comprises a demodulator configured to demodulate the received data transfer structure; and a decoder configured to decode the demodulated data transfer structure.

In addition, while a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it is understood that aspects of the disclosure may be implemented in discrete circuits, partially integrated circuits or fully integrated circuits or programming means. Also, the terms “exemplary”, “for example” and “e.g.” are merely meant as an example, rather than the best or optimal.

Although specific aspects have been illustrated and described herein, it will be appreciated by those of ordinary skill in the art that a variety of alternate and/or equivalent implementations maybe substituted for the specific aspects shown and described without departing from the scope of the present disclosure. This application is intended to cover any adaptations or variations of the specific aspects discussed herein.

What is claimed is:

1. A method for iterative decoding a data transfer structure comprising a plurality of code blocks, the method comprising:
decoding a code block of the data transfer structure in a first iteration;
determining a quantity indicative of a performance of the decoding of the code block;
if the quantity indicates a decoding failure, decoding the code block again in subsequent iterations until a stopping criterion is reached,
wherein the stopping criterion is based on a predetermined number of iterations per code block and a predetermined number of iterations per data transfer structure.

2. The method of claim 1,
wherein the predetermined number of iterations per data transfer structure is smaller than the predetermined number of iterations per code block times a number of code blocks contained in the data transfer structure.

3. The method of claim 1,
wherein determining the quantity comprises performing a cyclic redundancy check over at least part of the code block.

4. The method of claim 1, comprising:
decoding a next code block of the data transfer structure if the quantity indicates a success.

5. The method of claim 1, comprising:
stopping the decoding of the data transfer structure if either the predetermined number of iterations per code block or the predetermined number of iterations per data transfer structure is reached.

6. The method of claim 1,
wherein decoding the code block is based on Turbo decoding.

7. The method of claim 1,
wherein the predetermined number of iterations per data transfer structure is variable.

8. The method of claim 1,
wherein the predetermined number of iterations per data transfer structure depends on a code rate of the decoding.

9. The method of claim 1,
wherein the predetermined number of iterations per data transfer structure depends on a number of retransmissions of the code blocks.

10. The method of claim 1,
wherein the predetermined number of iterations per data transfer structure depends on a transmission bandwidth.

11. The method of claim 1,
wherein the predetermined number of iterations per data transfer structure depends on a throughput of the decoding.

12. The method of claim 1,
wherein the predetermined number of iterations per data transfer structure depends on a clock rate of the decoding.

13. The method of claim 1,
wherein the predetermined number of iterations per data transfer structure depends on a transmission scheme.

14. The method of claim 1,
wherein the predetermined number of iterations per data transfer structure depends on at least one of a layer, a channel and a carrier over which the code block is transmitted.

15. The method of claim 1,
wherein the predetermined number of iterations per data transfer structure depends on an evaluation of the statistics of the number of iterations needed for decoding a data transfer structure.

16. The method of claim 1, wherein the data transfer structure is a transport block in a mobile communication standard.

17. An iterative decoder for iterative decoding a data transfer structure comprising a plurality of code blocks, the iterative decoder comprising:
a code block decoder configured to iteratively decode a code block of the data transfer structure;
a quantity computation circuit configured to compute a quantity indicative of a performance of the decoding of the code block;
a stopping criterion computation circuit configured to compute a stopping criterion for the iterative code block decoding based on a predetermined number of iterations per code block and a predetermined number of iterations per data transfer structure.

18. The iterative decoder of claim 17,
wherein the quantity computation circuit comprises a CRC circuit configured to compute a cyclic redundancy check over at least part of the code block.

19. The iterative decoder of claim 17,
wherein the quantity computation circuit comprises a metric computation circuit configured to compute a metric of the decoding of the code block.

20. The iterative decoder of claim 17,
wherein the code block decoder comprises a Turbo decoder.

21. A method for iterative decoding a data transfer structure of a plurality of data transfer structures, the data transfer structure comprising a plurality of code blocks, the method comprising:
decoding a code block of the data transfer structure in a first iteration;
determining a quantity indicative of a performance of the decoding of the code block; and
if the quantity indicates a decoding failure, decoding the code block again in subsequent iterations until a stopping criterion is reached,
wherein the stopping criterion is based on a predetermined number of iterations per code block and a total available number of iterations with respect to the plurality of data transfer structures.

22. The method of claim 21,
wherein the total available number of iterations is smaller than the predetermined number of iterations per code block times a number of code blocks contained in the data transfer structure times a number of data transfer structures of the plurality of data transfer structures.

23. The method of claim 21,
wherein the total available number of iterations is shared between code blocks of different layers and/or code blocks of different carriers.

24. The method of claim 21, comprising:
determining a channel quality of the data transfer structure; and
decoding the code blocks of the data transfer structure based on the determined channel quality.

25. The method of claim 24, comprising:
prioritizing the decoding of the data transfer structure based on the determined channel quality.
